(19) United States
(12) Patent Application Publication
(10) Pub. No.: US 2020/0312968 A1
(43) Pub. Date: Oct. 1, 2020

(54) SEMICONDUCTOR APPARATUS

(71) Applicant: ADVANTEST CORPORATION, Tokyo (JP)

(72) Inventors: Kiyotaka KASAHARA, Tokyo (JP); Kensuke OKUMURA, Tokyo (JP); Tomoo YAMANOUCHI, Tokyo (JP)

(21) Appl. No.: 16/742,062

(22) Filed: Jan. 14, 2020

(30) Foreign Application Priority Data
Mar. 25, 2019 (JP) 2019-056904

(51) Int. Cl. H01L 29/40; H01L 29/417; H01L 29/20; H01L 29/778; H01L 29/205; H01L 29/16; H01L 29/78; H01L 29/812

(52) U.S. Cl. CPC H01L 29/404; H01L 29/41758; H01L 29/2003; H01L 29/7786; H01L 29/778; H01L 29/16; H01L 29/1608; H01L 29/78; H01L 29/812; H01L 29/205

(57) ABSTRACT

Planar transistors are integrated on a semiconductor apparatus. Each planar transistor includes a source electrode, a gate electrode, a drain electrode, and a field plate. The source electrode and the field plate are coupled on the outside of an active region of the planar transistor.

### CROSS REFERENCES TO RELATED APPLICATIONS

The present application claims priority under 35 U.S.C. § 119 to Japanese Patent Application 2019-056904, filed on Mar. 25, 2019, the entire contents of which being incorporated herein by reference.

### BACKGROUND OF THE INVENTION

### 1. Field of the Invention

The present invention relates to a semiconductor apparatus including a HEMT (High Electron Mobility Transistor).

### 2. Description of the Related Art

As substitutions for conventional silicon semiconductor devices, the development of nitride semiconductor devices having the potential to support high-voltage, high-speed operation has been advanced.

Compound semiconductor transistors have a planar transistor structure in the same manner as conventional Si transistors. With such a planar transistor, improvement of the breakdown voltage is limited due to the concentration of a reverse electric field applied between the gate and drain at an end of the gate electrode. In order to relax this limit so as to further improve the breakdown voltage, a field plate is provided. FIG. 1 is a cross-sectional diagram showing a planar transistor 10 including a field plate according to a conventional technique.

The planar transistor 10 includes a gate electrode (G) 12, a source electrode (S) 14, a drain electrode (D) 16, and a field plate (FP) 18. The field plate 18 is arranged such that it extends from the source electrode 14 toward the drain electrode 16 such that it overlaps a part of the gate electrode 12.

FIG. 1 shows an electric field distribution E provided by such a transistor including the field plate. By providing the field plate 18, the electric field strength distribution is dispersed into a peak at the end of the gate electrode 12 and another peak at the end of the field plate 18. This allows the transistor breakdown voltage to be improved.

As a result of investigating the planar transistor 10 shown in FIG. 1, the present inventor has come to recognize the following problem.

With the device structure shown in FIG. 1, the gate electrode 12 and the field plate 18 overlap. This overlap leads to the occurrence of a parasitic capacitance between the gate and the source of the transistor. This parasitic capacitance acts as an input capacitance of the transistor, which becomes a cause of hindering a high-speed switching operation.

### SUMMARY OF THE INVENTION

The present invention has been made in view of such a situation. Accordingly, it is an exemplary purpose of an embodiment of the present invention to provide a planar transistor that is capable of supporting a high-speed operation.

A semiconductor apparatus according to an embodiment of the present invention includes a planar transistor. The planar transistor includes a source electrode, a gate electrode, a drain electrode, and a field plate. The source electrode and the field plate are coupled on the outside of an active region of the planar transistor.

With this embodiment, there is no overlap between the field plate and the gate electrode. Furthermore, there is no overlap between the gate electrode and the coupling line that couples the field plate and the source electrode. This arrangement allows the input capacitance of the transistor to be reduced, thereby providing high-speed operation. With a structure in which there is overlap between the field plate and the gate electrode, such an arrangement has the potential to cause step disconnection. Also, in a case in which the source electrode and the field plate are coupled across the gate electrode, such a structure has the potential to cause a step disconnection in the coupling line. This embodiment allows the line that couples the field plate and the source electrode to be formed in a flat region. This arrangement solves a problem of step disconnection, thereby providing improved reliability.

Also, the planar transistor may have a multi-finger structure.

Also, the planar transistor may be structured as a GaN-HEMT (High Electron Mobility Transistor). Also, the GaN-HEMT may be structured to have a MIS structure.

It is to be noted that any arbitrary combination or rearrangement of the above-described structural components and so forth is effective as and encompassed by the present embodiments. Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional diagram showing a conventional planar transistor including a field plate;

FIG. 2A is a cross-sectional diagram showing a semiconductor apparatus according to an embodiment, and FIG. 2B is a plan view of a planer transistor;

FIG. 3 is a circuit diagram showing a resistance load inverter circuit that was used for performance comparison;

FIG. 4A and FIG. 4B are diagrams showing a turn-on operation in a case in which the inverter circuit shown in FIG. 3 is configured using the planar transistor shown in FIG. 1 and a turn-on operation in a case in which the inverter circuit shown in FIG. 3 is configured using the planar transistor shown in FIG. 2.

FIG. 5A and FIG. 5B are diagrams showing a turn-off operation in a case in which the inverter circuit shown in FIG. 3 is configured using the planer transistor shown in FIG. 1 and a turn-off operation in a case in which the inverter circuit shown in FIG. 3 is configured using the planer transistor shown in FIG. 2;

FIG. 6 is a diagram showing measurement results of (i) leak current of the planar transistor shown in FIG. 1 and (ii) leak current of the planar transistor shown in FIG. 2;

FIG. 7A and FIG. 7B are diagrams showing SEM cross-section images of the planar transistor shown in FIG. 1 and the planar transistor shown in FIG. 2, respectively;

FIG. 8A is a cross-sectional diagram showing a semiconductor apparatus according to a modification 1, FIG. 8B is a diagram showing an electric field strength distribution, and FIG. 8C is a plan view of a planar transistor; and

FIG. 9 is a plan view of a planer transistor according to a modification 2.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In some cases, the sizes (thickness, length, width, and the like) of each component shown in the drawings are expanded or reduced as appropriate for ease of understanding. The size relation between multiple components in the drawings does not necessarily match the actual size relation between them. That is to say, even in a case in which a given member A has a thickness that is larger than that of another member B in the drawings, in some cases, in actuality, the member A has a thickness that is smaller than that of the member B.

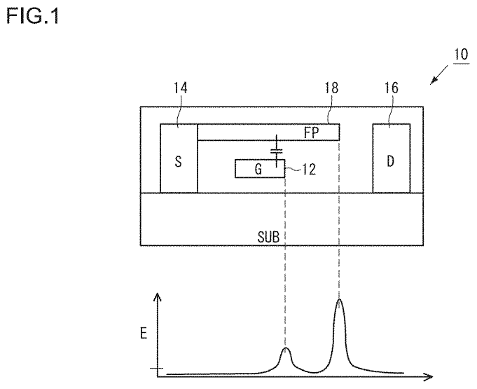

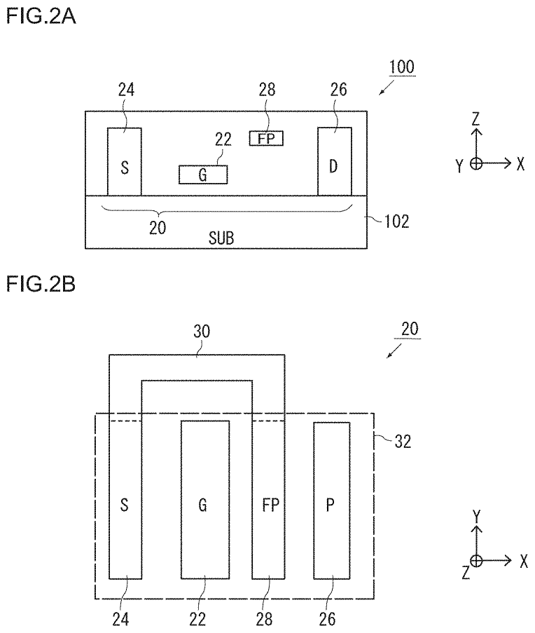

FIG. 2A is a cross-sectional diagram showing a semiconductor apparatus 100 according to an embodiment. FIG. 2B is a plan view of a planar transistor 20. Multiple planar transistors 20 are integrated on the semiconductor apparatus 20. However, FIG. 1 shows only a single transistor 20.

The planar transistor 20 includes a gate electrode 22, a source electrode 24, a drain electrode 26, a field plate 28, and coupling line 30 formed on an epitaxial substrate 102. The kind of the planar transistor 20 is not restricted in particular. For example, the planar transistor 20 may be configured as a GaN-HEMT or GaAs-HEMT. The planar transistor 20 may be configured as an enhancement-type transistor (normally off transistor). The planar transistor 20 may have a MIS structure including an insulating film between the gate electrode 22 and the epitaxial substrate 102. Alternatively, the planar transistor 20 may be configured as a depletion mode (normally on) transistor. The planar transistor 20 may have a Schottky structure in which the gate electrode 22 is arranged such that it is in contact with the epitaxial substrate 102.

The epitaxial substrate 102 includes at least an electron transit layer and an electron supply layer. As an example, the electron transit layer may be configured as a GaN layer. The electron supply layer may be configured as an AlGaN layer.

The gate electrode 22, the source electrode 24, the drain electrode 26, and the field plate 28 are arranged side-by-side in a second direction (x direction in the drawing) in the order of the source electrode 24, the gate electrode 22, the field plate 28, and the drain electrode 26 with their longitudinal direction as a first direction (y-axis direction in the drawing). In the present embodiment, the field plate 28 is designed to have a height that is larger than that of the gate electrode 22.

As shown in FIG. 2B, the source electrode 24 and the field plate 28 are coupled in a planar manner via the coupling line 30 configured on the outside of an active region 32 of the planar transistor 20.

The above is the structure of the semiconductor apparatus 100. Next, description will be made regarding the effects thereof. With the semiconductor apparatus 100 (planar transistor 20) according to the embodiment, there is no overlap between the field plate 28 and the gate electrode 22. Furthermore, there is no overlap between the coupling line 30 and the gate electrode 22. Accordingly, this allows a parasitic capacitance between the gate electrode 22 and the coupling line 30 to be reduced as compared with the structure shown in FIG. 1. This allows the input capacitance of the planar transistor 20 to be reduced, thereby providing high-speed operation.

Description will be made regarding the result of a performance comparison between an actually formed planar transistor 10 shown in FIG. 1 and planar transistor 20 shown in FIG. 2.

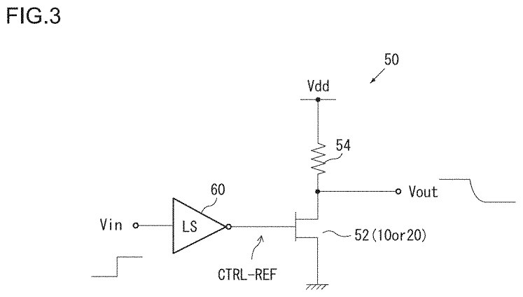

FIG. 3 is a circuit diagram showing a resistance load inverter circuit that was used for the performance comparison. An inverter circuit 50 includes a transistor 52 and a resistor 54. The source of the transistor 52 is grounded. A resistor 54 is provided between the drain of the transistor 52 and a power supply line. The transistor 52 is configured as a normally on device. A driver 60 is configured as an inverting level shifter. The driver 60 drives the gate of the transistor 52 according to an input signal Vin. The response speed is compared between a case in which the transistor 52 shown in FIG. 3 is configured as the planar transistor 10 shown in FIG. 1 and a case in which the transistor 52 shown in FIG. 3 is configured as the planar transistor 20 shown in FIG. 2.

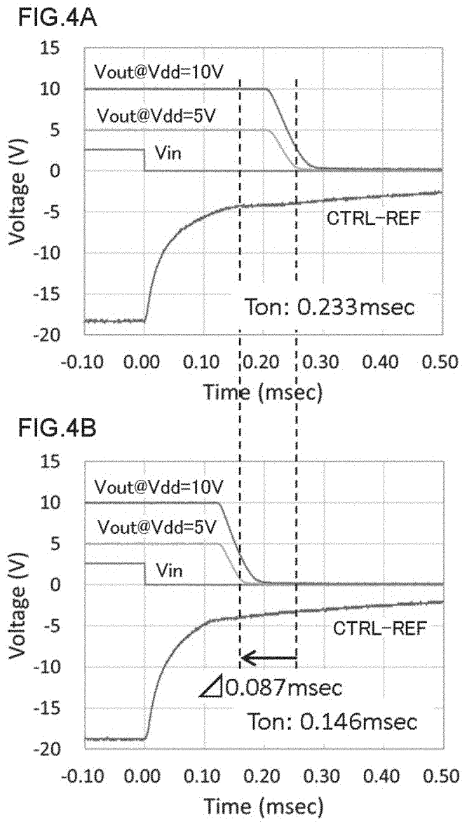

FIG. 4A and FIG. 4B are diagrams respectively showing the turn-on operation in a case in which the inverter circuit 50 shown in FIG. 3 is configured using the planar transistor 10 shown in FIG. 1 and the turn-on operation in a case in which the inverter circuit 50 shown in FIG. 3 is configured using the planar transistor 20 shown in FIG. 2. The turn-on operation is measured under two voltage conditions, i.e., with a power supply voltage Vdd of 5 V and 10 V. As shown in FIG. 4A, in a case of employing the planar transistor 10 shown in FIG. 1, the inverter circuit 50 operates with a turn-on time Ton of 0.233 ms. In contrast, as shown in FIG. 4B, in a case of employing the planar transistor 20 shown in FIG. 2, the inverter circuit 50 operates with a turn-on time Ton of 0.146 ms. Such an arrangement provides a turn-on time reduced by 0.087 ms as compared with an arrangement employing the planar transistor 10 shown in FIG. 1.

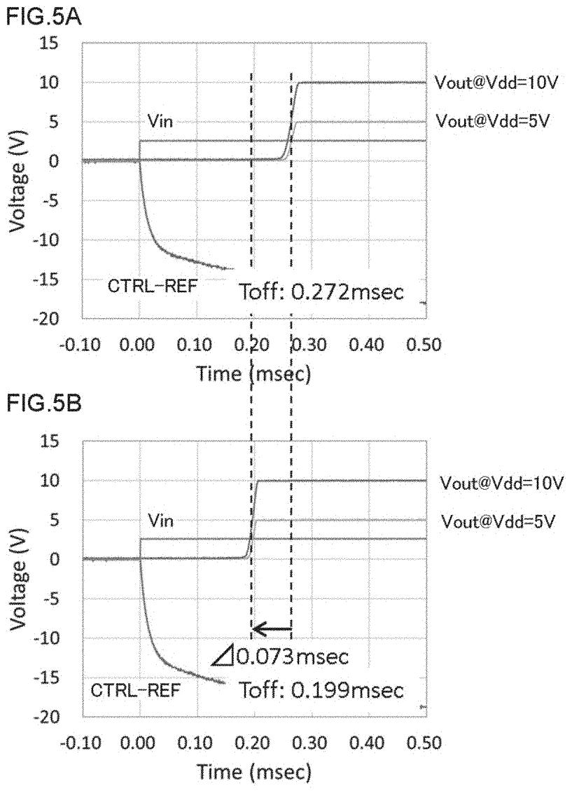

FIG. 5A and FIG. 5B are diagrams respectively showing the turn-off operation in a case in which the inverter circuit 50 shown in FIG. 3 is configured using the planar transistor 10 shown in FIG. 1 and the turn-off operation in a case in which the inverter circuit 50 shown in FIG. 3 is configured using the planar transistor 20 shown in FIG. 2. As shown in FIG. 5A, in a case of employing the planar transistor 10 shown in FIG. 1, the inverter circuit 50 operates with a turn-off time Toff of 0.272 ms. In contrast, as shown in FIG. 5B, in a case of employing the planar transistor 20 shown in FIG. 2, the inverter circuit operates with a turn-off time Toff of 0.199 ms. Such an arrangement provides a turn-off time reduced by 0.073 ms as compared with an arrangement employing the planar transistor 10 shown in FIG. 1.

As described above, the planar transistor 10 shown in FIG. 2 allows the gate-source capacitance to be reduced, thereby providing high-speed operation.

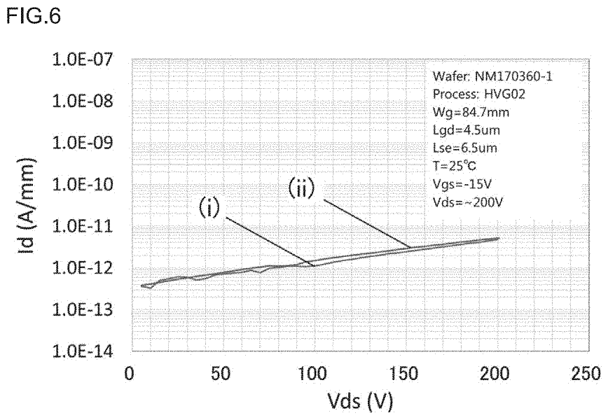

FIG. 6 is a diagram showing measurement results of (i) leak current of the planar transistor 10 shown in FIG. 1 and (ii) leak current of the planar transistor 20 shown in FIG. 2. As can be understood from FIG. 6, the planar transistor 20 shown in FIG. 2 provides equivalently high performance as compared with the planar transistor 10 shown in FIG. 1.

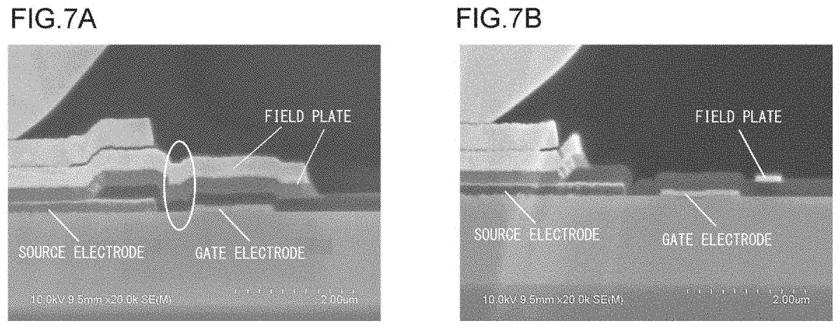

FIG. 7A and FIG. 7B are diagrams showing SEM cross-section images of the planar transistor 10 shown in FIG. 1 and the planar transistor 20 shown in FIG. 2, respectively. The SEM cross-section images are each acquired in the active region of the transistor. As shown in FIG. 7A, with the planar transistor 10 shown in FIG. 1, the source electrode and the field plate are arranged such that they cross each other. Such a structure has a high potential to cause a step disconnection at an end of the gate electrode.

In contrast, as shown in FIG. 7B, the planar transistor 20 shown in FIG. 2 does not include the coupling line 30 in the active region. Accordingly, there is no need for concern regarding the occurrence of a step disconnection, thereby providing improved device reliability.

Furthermore, with the present embodiment, there is no need to form a via hole within the active region, which is also an advantage.

Description has been made above regarding the present invention with reference to the embodiment. The above-described embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the technical scope of the present invention. Description will be made below regarding such modifications.

### Modification 1

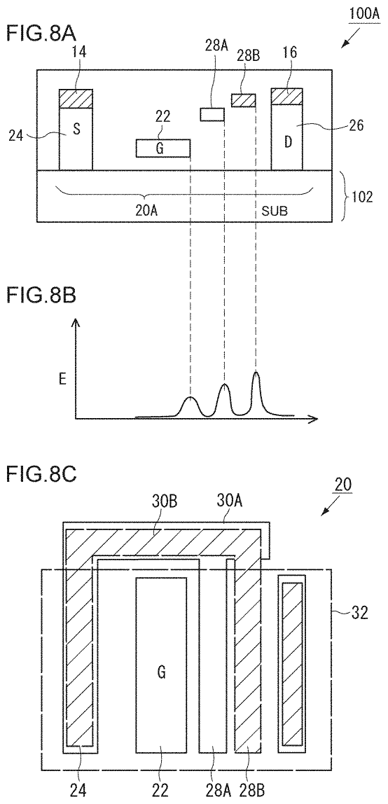

FIG. 8A is a cross-sectional diagram showing a semiconductor apparatus 100A according to a modification 1. FIG. 8B is a diagram showing an electric field strength distribution thereof. FIG. 8C is a plan view of a planar transistor 20A.

The semiconductor apparatus 100A is configured such that the planar transistors 20A are integrated on it. Each planar transistor 20A includes multiple field plates 28A and 28B. That is to say, the source electrode 24, the gate electrode 22, the field plates 28A and 28B, and the drain electrode 26 are arranged in this order. The field plates 28A and 28B are formed with different heights designed in a stepwise manner as viewed in a cross-sectional view. Specifically, each field plate 28 is designed to have a larger height as the distance between it and the gate electrode 22 becomes grater.

By providing the multiple field plates 28A and 28B, this arrangement is capable of further relaxing the electric field concentration, thereby providing further improved breakdown voltage.

As shown in FIG. 8C, with the modification 1, the field plates 28A and 28B are coupled to the source electrode 24 on the outside of the active region 32. The coupling line 30A that couples the field plate 28A and the source electrode 24 and the coupling line 30B that couples the field plate 28B and the source electrode 24 are layered.

Description has been made above regarding an arrangement including two field plates. Also, three or more field plates may be provided. This arrangement is capable of further relaxing the electric field concentration.

### Modification 2

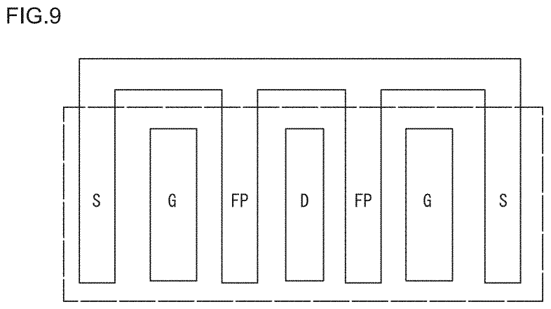

FIG. 9 is a plan view of a planar transistor 20B according to a modification 2. The planar transistor 20B has a multi-finger structure. In the multi-finger structure, a field plate is provided for each finger (each pair of a gate electrode and a source electrode).

The modification 1 and the modification 2 may be combined. That is to say, the planar transistor 20B having such a multi-finger structure may be designed such that multiple field plates are provided for each finger.

### Modification 3

Description has been made in the embodiment regarding an arrangement in which the planar transistor 20 is configured as a HEMT. However, the present invention is not restricted to such an arrangement. Also, the planar transistor 20 may be configured as a Si-FET (Field Effect Transistor). Also, the semiconductor material and the device structure thereof are not restricted.

While the preferred embodiments of the present invention have been described using specific terms, such description is for illustrative purposes only, and it is to be understood that changes and variations may be made without departing from the spirit or scope of the appended claims.

What is claimed is:

1. A semiconductor apparatus comprising a planar transistor, wherein the planar transistor comprises a source electrode, a gate electrode, a drain electrode, and a field plate,
and wherein the source electrode and the field plate are coupled on the outside of an active region of the planar transistor.

2. The semiconductor apparatus according to claim 1, wherein the field plate has a height that is larger than that of the gate electrode.

3. The semiconductor apparatus according to claim 1, wherein the planar transistor comprises a plurality of field plates,
and wherein the plurality of field plates are provided with different heights.

4. The semiconductor apparatus according to claim 3, wherein the height of each of the field plates becomes larger as the distance between the field plate and the gate electrode becomes grater.

5. The semiconductor apparatus according to claim 3, wherein a plurality of coupling lines that couple the plurality of field plates to the source electrode are layered.

6. The semiconductor apparatus according to claim 4, wherein a plurality of coupling lines that couple the plurality of field plates to the source electrode are layered.

7. The semiconductor apparatus according to claim 1, wherein the planar transistor has a multi-finger structure.

8. The semiconductor apparatus according to claim 1, wherein the planar transistor is structured as any one from among a GaN-HEMT (High Electron Mobility Transistor), a GaAs-HEMT, a Si-FET, and a SiC-FET.

9. The semiconductor apparatus according to claim 1, having a MIS (Metal Insulator Semiconductor) structure in which an insulating film is formed between the gate electrode and an epitaxial substrate.

10. The semiconductor apparatus according to claim 1, having a Schottky structure in which the gate electrode is in contact with an epitaxial substrate.
